(19) United States
(12) Patent Application Publication
(10) Pub. No.: US 2024/0120430 A1
(43) Pub. Date: Apr. 11, 2024

(54) Method of Forming Infrared Detector

(71) Applicant: Hon Young Semiconductor Corporation, Hsinchu City (TW)

(72) Inventor: Yen-Chang CHEN, Hsinchu City (TW)

(21) Appl. No.: 18/170,521

(22) Filed: Feb. 16, 2023

(30) Foreign Application Priority Data
Oct. 11, 2022 (TW) 111138462

(51) Int. Cl. H01L 31/18; H01L 31/101

(52) U.S. Cl. CPC H01L 31/18; H01L 31/101

(57) ABSTRACT

A method of forming infrared detector includes the following operations. A sensing structure including a first infrared absorption layer, a first protection layer, a second infrared absorption layer, and a second protection layer from bottom to top is received. A patterned photoresist layer is formed on the sensing structure, in which the patterned photoresist layer has a first opening exposing the second protection layer. The second protection layer is etched through the first opening to form a second opening in the second protection layer, in which the second opening exposes the second infrared absorption layer. The patterned photoresist layer is removed. The second infrared absorption layer and the first protection layer are etched through the second opening to form a third opening, in which the third opening exposes the first infrared absorption layer. An electrode is formed in the third opening.

### CROSS-REFERENCE TO RELATED APPLICATION

This application claims priority to Taiwan Application Serial Number 111138462, filed Oct. 11, 2022, which is herein incorporated by reference.

### BACKGROUND

### Field of Invention

The present disclosure relates to a method of forming infrared detector.

### Description of Related Art

Infrared detectors that detect the infrared light of the surrounding environment are used in medicine, aviation, monitoring, and so on. In these infrared detectors, sensing materials change the temperatures after absorbing the infrared light, which also causes the resistance values of the sensing materials to change. Therefore, the infrared light of the environment can be sensed by measuring the change in the resistance value. To obtain an accurate and sensitive change of the resistance value in a low detection limit, it is necessary to develop a method of forming the infrared detector having the above-mentioned advantages.

### SUMMARY

The present disclosure relates to a method of forming infrared detector. The method includes the following operations. A sensing structure including a first infrared absorption layer, a first protection layer, a second infrared absorption layer, and a second protection layer from bottom to top is received. A patterned photoresist layer on the sensing structure is formed, in which the patterned photoresist layer has a first opening exposing the second protection layer. The second protection layer is etched through the first opening to form a second opening in the second protection layer, in which the second opening exposes the second infrared absorption layer. The patterned photoresist layer is removed. The second infrared absorption layer and the first protection layer are etched through the second opening to form a third opening that penetrates the second protection layer, the second infrared absorption layer, and the first protection layer, in which the third opening exposes the first infrared absorption layer. An electrode is formed in the third opening.

In some embodiments, the electrode is in direct contact with the first infrared absorption layer.

In some embodiments, the first protection layer and the second protection layer independently include silicon nitride, silicon oxide, tetraethoxysilane, or combinations thereof.

In some embodiments, a thickness of the second protection layer is greater than a thickness of the first protection layer.

In some embodiments, a thickness of the second protection layer is between 1500 Å and 2500 Å.

In some embodiments, the second infrared absorption layer includes titanium, vanadium, amorphous silicon, or combinations thereof.

In some embodiments, a thickness of the second infrared absorption layer is between 100 Å and 200 Å.

In some embodiments, the first infrared absorption layer includes vanadium oxide, vanadium, titanium, amorphous silicon, or combinations thereof.

In some embodiments, etching the second infrared absorption layer and the first protection layer through the second opening is performed by using an etching gas that includes Cl₂, BCl₃, or a combination thereof.

In some embodiments, the method further includes etching an upper portion of the second protection layer when etching the second infrared absorption layer and the first protection layer through the second opening.

In some embodiments, the second protection layer has a remaining portion on the second infrared absorption layer after etching the upper portion of the second protection layer.

In some embodiments, a thickness of the remaining portion of the second protection layer is between 800 Å and 1900 Å.

The present disclosure also relates to a method of forming infrared detector. The method includes the following operations. A sensing structure including an infrared absorption layer and a protection layer from bottom to top is received. A patterned photoresist layer on the sensing structure is formed, in which the patterned photoresist layer has a first opening exposing the protection layer. A first portion of the protection layer is etched through the first opening to form a second opening in the protection layer, in which a second portion of the protection layer remains under the second opening. The patterned photoresist layer is removed. The second portion of the protection layer is etched through the second opening to form a third opening that penetrates the protection layer, in which the third opening exposes the infrared absorption layer. An electrode is formed in the third opening.

In some embodiments, the protection layer includes silicon nitride, silicon oxide, tetraethoxysilane, or combinations thereof.

In some embodiments, the infrared absorption layer includes vanadium oxide, vanadium, titanium, amorphous silicon, or combinations thereof.

In some embodiments, the method further includes etching an upper portion of the protection layer when etching the second portion of the protection layer through the second opening.

The present disclosure yet also relates to a method of forming infrared detector. The method includes the following operations. A sensing structure including an infrared absorption layer, a first protection layer, and a second protection layer from bottom to top is received, in which a material of the first protection layer is different than a material of the second protection layer. A patterned photoresist layer on the sensing structure is formed, in which the patterned photoresist layer has a first opening exposing the second protection layer. The second protection layer is etched through the first opening to form a second opening in the second protection layer, in which the second opening exposes the first protection layer. The patterned photoresist layer is removed. The first protection layer is etched through the second opening to form a third opening that penetrates the first protection layer and the second protection layer, in which the third opening exposes the infrared absorption layer. An electrode is formed in the third opening.

In some embodiments, the first protection layer includes silicon nitride, silicon oxide, tetraethoxysilane, or combinations thereof, and the second protection layer includes silicon nitride, silicon oxide, tetraethoxysilane, or combinations thereof.

In some embodiments, the infrared absorption layer includes vanadium oxide, vanadium, titanium, amorphous silicon, or combinations thereof.

In some embodiments, the method further includes etching an upper portion of the second protection layer when etching the first protection layer through the second opening.

### BRIEF DESCRIPTION OF THE DRAWINGS

Aspects of the present disclosure are best understood from the following detailed description when reading with the accompanying figures. It is noted that, in accordance with the standard practice of the industry, various features are not drawn to scale. In fact, the dimensions of the various features may be arbitrarily increased or reduced for clarity of discussion.

FIG. 1 is a flowchart of a method of forming an infrared detector in accordance with some embodiments of the present disclosure.

FIGS. 2 to 6 are schematics of the infrared detector during the formation stages in accordance with some embodiments of the present disclosure.

FIG. 7 is a flowchart of a method of forming an infrared detector in accordance with some embodiments of the present disclosure.

FIGS. 8 to 12 are schematics of the infrared detector during the formation stages in accordance with some embodiments of the present disclosure.

FIG. 13 is a flowchart of a method of forming an infrared detector in accordance with some embodiments of the present disclosure.

FIGS. 14 to 18 are schematics of the infrared detector during the formation stages in accordance with some embodiments of the present disclosure.

### DETAILED DESCRIPTION

To make the description of the present disclosure more detailed and complete, explanatory descriptions of the aspects and specific implementations of the embodiments are provided below. It is not to limit the embodiments of the present disclosure to only one form. The embodiments of the present disclosure can combine or be substituted with each other under beneficial circumstances. Other embodiments may be appended without further description or explanation.

In addition, spatially relative terms, such as below and above, etc., may be used in the present disclosure to describe the relationship of one element or feature to another element or feature in the figures. Besides the orientation depicted in the figures, spatially relative terms may encompass different orientations of the device in use or operation. For example, the device may be otherwise oriented (e.g., rotated 90 degrees or otherwise) and the spatially relative terms of the present disclosure can be interpreted accordingly. In the present disclosure, unless otherwise indicated, the same element numbers in different figures refer to the same or similar elements formed from the same or similar materials by the same or similar methods.

The present disclosure relates to a method of forming infrared detector. The method includes the following operations. A sensing structure including a first infrared absorption layer, a first protection layer, a second infrared absorption layer, and a second protection layer from bottom to top is received. A patterned photoresist layer on the sensing structure is formed, in which the patterned photoresist layer has a first opening exposing the second protection layer. The second protection layer is etched through the first opening to form a second opening in the second protection layer, in which the second opening exposes the second infrared absorption layer. The patterned photoresist layer is removed. The second infrared absorption layer and the first protection layer are etched through the second opening to form a third opening that penetrates the second protection layer, the second infrared absorption layer, and the first protection layer, in which the third opening exposes the first infrared absorption layer. An electrode is formed in the third opening. The method of forming infrared detector in the present disclosure will be explained in detail in the following paragraphs.

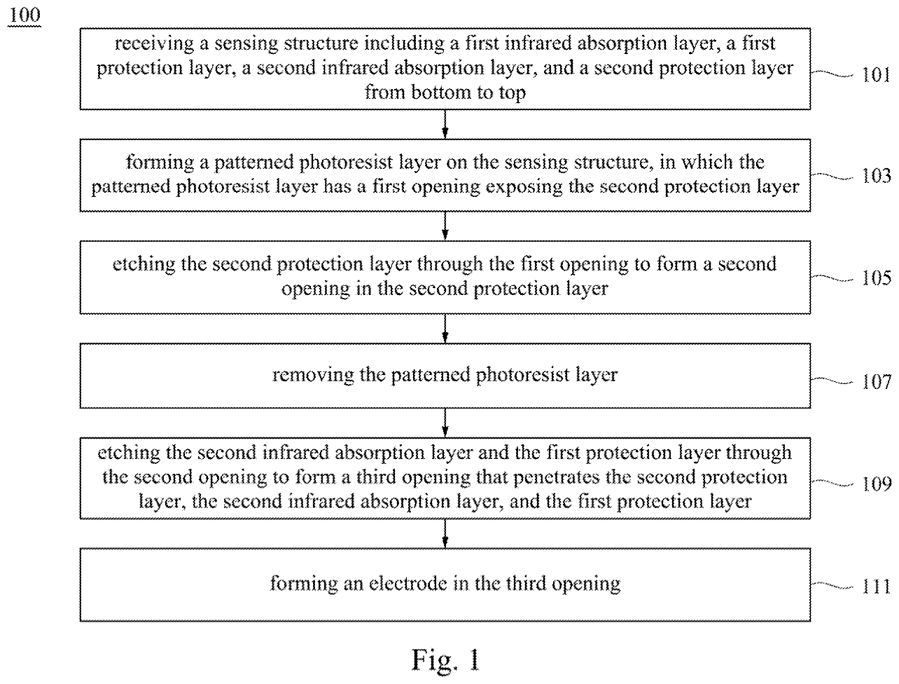

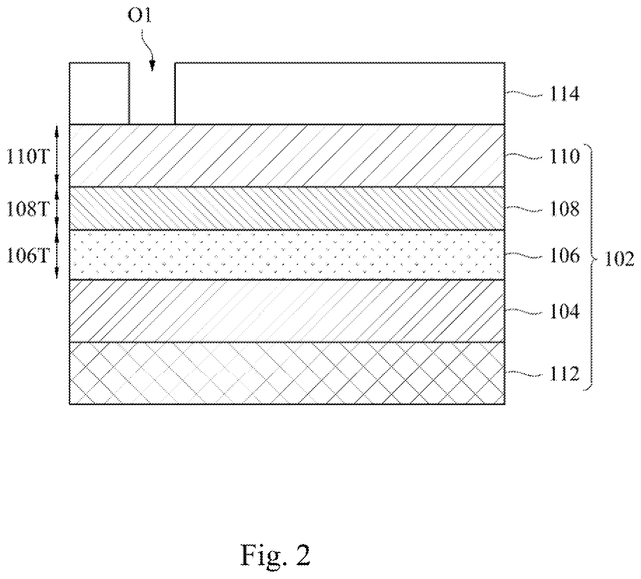

FIG. 1 is a flowchart of a method 100 of forming an infrared detector in accordance with some embodiments of the present disclosure. FIGS. 2 to 6 are schematics of the infrared detector during the formation stages in the method 100 shown in FIG. 1, in accordance with some embodiments of the present disclosure. Please refer to FIGS. 2 to 6 when reading FIG. 1.

In FIG. 1, the method 100 includes an operation 101. A sensing structure 102 is received, in which the sensing structure 102 includes a first infrared absorption layer 104, a first protection layer 106, a second infrared absorption layer 108, and a second protection layer 110, which are stacked from bottom to top, as shown in FIG. 2. The first infrared absorption layer 104 and the second infrared absorption layer 108 can absorb infrared light and change the resistance values by changing their temperatures. The first protection layer 106 and the second protection layer 110 respectively protect the first infrared absorption layer 104 and the second infrared absorption layer 108 located underneath, in order to avoid ambient moisture and/or oxygen affecting the functional performances of the first infrared absorption layer 104 and the second infrared absorption layer 108. In addition, the first protection layer 106 and the second protection layer 110 may also absorb infrared light, thereby not affecting the function performances of the first infrared absorption layer 104 and the second infrared absorption layer 108 while protecting the first infrared absorption layer 104 and the second infrared absorption layer 108. It should be noted that the number of layers shown in FIG. 2 is an example. As long as the infrared absorption layer is located between the protection layers and protected by the protection layers, any numbers of the infrared absorption layers and the protection layers are in the scope of the present disclosure. However, the example shown in FIG. 2 is the preferable example. In some embodiments, the first infrared absorption layer 104 includes vanadium oxide, vanadium, titanium, amorphous silicon, or combinations thereof. In some embodiments, the second infrared absorption layer 108 includes titanium, vanadium, amorphous silicon, or combinations thereof. A thickness 108T of the second infrared absorption layer 108 is between 100 Å and 200 Å. In some embodiments, the first protection layer 106 and the second protection layer 110 independently include silicon nitride, silicon oxide, tetraethoxysilane, or combinations thereof. A thickness 106T of the first protection layer 106 is between 500 Å and 1000 Å. A thickness 110T of the second protection layer 110 is between 1500 Å and 2500 Å. In some embodiments, the thickness 110T of the second protection layer 110 is greater than the thickness 106T of the first protection layer 106. In some embodiments, the sensing structure 102 further includes a buffer layer 112 located below the first infrared absorption layer 104. The buffer layer 112 protects the first infrared absorption layer 104 to avoid ambient moisture and/or oxygen affecting the functional performance of the first infrared absorption layer 104. In some embodiments, the buffer layer 112 includes silicon nitride, silicon oxide, tetraethoxysilane, or combinations thereof.

In FIG. 1, the method 100 includes an operation 103. A patterned photoresist layer 114 is formed on the sensing structure 102, in which the patterned photoresist layer 114 has a first opening O1 exposing the second protection layer 110, as shown in FIG. 2. In some embodiments, a photoresist layer (not shown) is formed on the sensing structure 102, and then a portion of the photoresist layer is selectively exposed to actinic radiation. When the material of the photoresist layer includes a positive photoresist, the portion of the photoresist layer that is exposed to actinic radiation is removed during the development process, and the non-exposed portion of the photoresist layer that is not exposed to actinic radiation is remained during the development process. After the development process, the first opening O1 of the patterned photoresist layer 114 is formed, as shown in FIG. 2. When the material of the photoresist layer includes a negative photoresist, the portion of the photoresist layer that is exposed to actinic radiation is remained during the development process, and the non-exposed portion of the photoresist layer that is not exposed to actinic radiation is removed during the development process. After the development process, the first opening O1 of the patterned photoresist layer 114 is formed, as shown in FIG. 2. In some embodiments, the material of the patterned photoresist layer 114 includes poly(methyl methacrylate) (PMMA), epoxy resin, phenolic resin, etc.

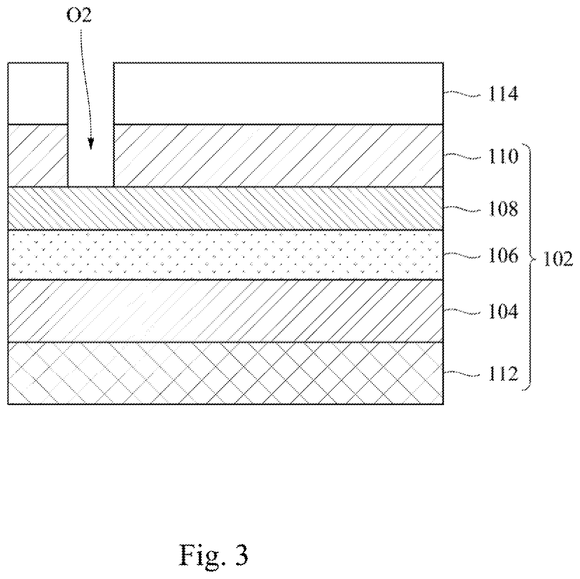

In FIG. 1, the method 100 includes an operation 105. The second protection layer 110 is etched through the first opening O1 to form a second opening O2 in the second protection layer 110, in which the second opening O2 exposes the second infrared absorption layer 108, as shown in FIG. 3. In some embodiments, etching the second protection layer 110 through the first opening O1 is performed by using an etching gas that includes Cl₂, BCl₃, or a combination thereof.

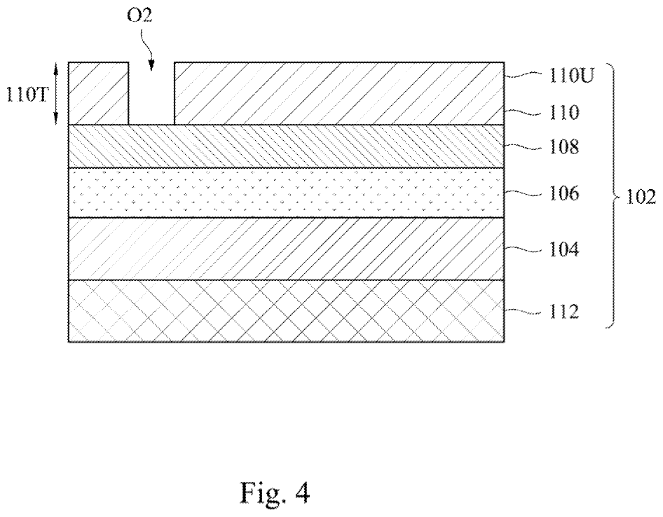

In FIG. 1, the method 100 includes an operation 107. The patterned photoresist layer 114 is removed, as shown in FIG. 4. In some embodiments, removing the patterned photoresist layer 114 is performed by using oxygen plasma.

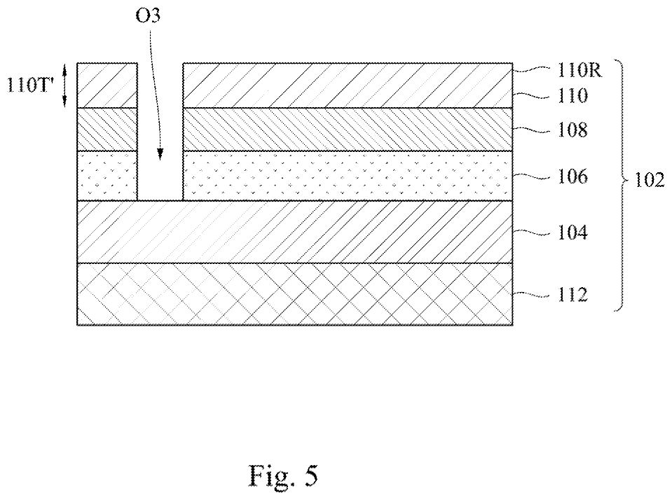

In FIG. 1, the method 100 includes an operation 109. The second infrared absorption layer 108 and the first protection layer 106 are etched through the second opening O2 to form a third opening O3 that penetrates the second protection layer 110, the second infrared absorption layer 108, and the first protection layer 106, in which the third opening O3 exposes the first infrared absorption layer 104, as shown in FIG. 5. The operation 109 further includes etching an upper portion 110U of the second protection layer 110 (see FIG. 4) when etching the second infrared absorption layer 108 and the first protection layer 106 through the second opening O2, thereby reducing the thickness of the second protection layer 110 (see FIG. 5). After etching the upper portion 110U of the second protection layer 110, the second protection layer 110 has a remaining portion 110R on the second infrared absorption layer 108, and when the third opening O3 is formed, the third opening O3 penetrates the remaining portion 110R of the second protection layer 110, the second infrared absorption layer 108, and the first protection layer 106. In the operation 109, the whole upper surface of the second protection layer 110 is etched. In the operation 109, the second infrared absorption layer 108 that is exposed by the second opening O2 of the second protection layer 110 and the first protection layer 106 that is right below the exposed second infrared absorption layer 108 are etched through the second opening O2 of the second protection layer 110. The operation of forming the third opening O3 avoids using the photoresist, thereby avoiding damaging the first infrared absorption layer 104 and the second infrared absorption layer 108 that are exposed by the third opening O3 in the process of removing the photoresist. The operation 109 of not using the photoresist also avoids additional residue formed on the first infrared absorption layer 104 and the second infrared absorption layer 108 that are exposed in the process of removing the photoresist. The additional residue may affect the functional performances of the first infrared absorption layer 104 and the second infrared absorption layer 108. For example, additional oxides may form in the process of using the oxygen plasma to remove the photoresist. In some embodiments, a thickness 110T′ of the remaining portion 110R of the second protection layer 110 is between 800 Å and 1900 Å. In some embodiments, etching the second infrared absorption layer 108, the first protection layer 106, and the upper portion 110U of the second protection layer 110 through the second opening O2 is performed by using an etching gas including Cl₂, BCl₃, or a combination thereof.

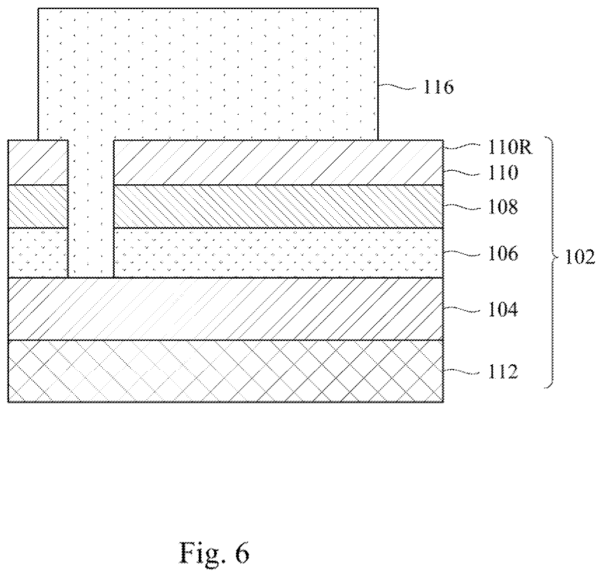

In FIG. 1, the method 100 includes an operation 111. An electrode 116 is formed in the third opening O3, as shown in FIG. 6. The operation 111 further includes forming the electrode 116 on the second protection layer 110 or on the remaining portion 110R of the second protection layer 110. The electrode 116 is in direct contact with the first infrared absorption layer 104 and the second infrared absorption layer 108 that are exposed by the third opening O3. The electrode 116 with the connection to the external wires (not shown) measures the changes in the resistance values of the first infrared absorption layer 104 and the second infrared absorption layer 108. Because avoid using the photoresist in the formation of the third opening O3, the electrode 116 formed in the operation 111 has good contact surfaces with the first infrared absorption layer 104 and the second infrared absorption layer 108. The good contact surfaces lead to small contact resistance, for example, the contact resistance being between 100 Kohm and 500 Kohm. The small contact resistance means the electrode 116 measures the changes in the resistance values caused by absorbing the infrared light in the first infrared absorption layer 104 and the second infrared absorption layer 108 more accurately and sensitively. Also, because the measurement error is reduced, the change in the resistance value that the electrode 116 can measure is small. In some embodiments, the material of the electrode 116 includes titanium, titanium nitride, vanadium, tungsten, aluminum-copper (Al—Cu), aluminum-silicon-copper (Al—Si—Cu), or combinations thereof.

In contrast, in the comparative embodiment of using the photoresist to form the third opening (not drawn), the photoresist is formed on the sensing structure of FIG. 4. The photoresist has an opening on the second opening of FIG. 4. Later, the second infrared absorption layer and the first protection layer that are under the second opening of FIG. 4 are etched through the opening of the photoresist. The result is the third opening of FIG. 5, which penetrates the second protection layer, the second infrared absorption layer, and the first protection layer. Later, the photoresist is removed and the electrode of FIG. 6 is formed in the third opening of FIG. 5. In the comparative embodiment, the third opening is formed by using the photoresist so that the process of removing the photoresist (e.g., a plasma process) damages the first infrared absorption layer and the second infrared absorption layer that are exposed by the third opening or leads to the residues formed on the exposed first infrared absorption layer and second infrared absorption layer. The damage and the residues cause high contact resistance between the electrode and the first infrared absorption layer and the second infrared absorption layer in the comparative embodiment, for example, between 1000 Kohm and 2000 Kohm. The comparative embodiment failed to accurately and sensitively measure the changes in the resistance values of the first infrared absorption layer and the second infrared absorption layer when absorbing the infrared light. The comparative embodiment also failed to measure a smaller change of the resistance value.

The present disclosure also relates to a method of forming infrared detector. The method includes the following operations. A sensing structure including an infrared absorption layer and a protection layer from bottom to top is received. A patterned photoresist layer on the sensing structure is formed, in which the patterned photoresist layer has a first opening exposing the protection layer. A first portion of the protection layer is etched through the first opening to form a second opening in the protection layer, in which a second portion of the protection layer remains under the second opening. The patterned photoresist layer is removed. The second portion of the protection layer is etched through the second opening to form a third opening that penetrates the protection layer, in which the third opening exposes the infrared absorption layer. An electrode is formed in the third opening. The method of forming infrared detector in the present disclosure will be explained in detail in the following paragraphs.

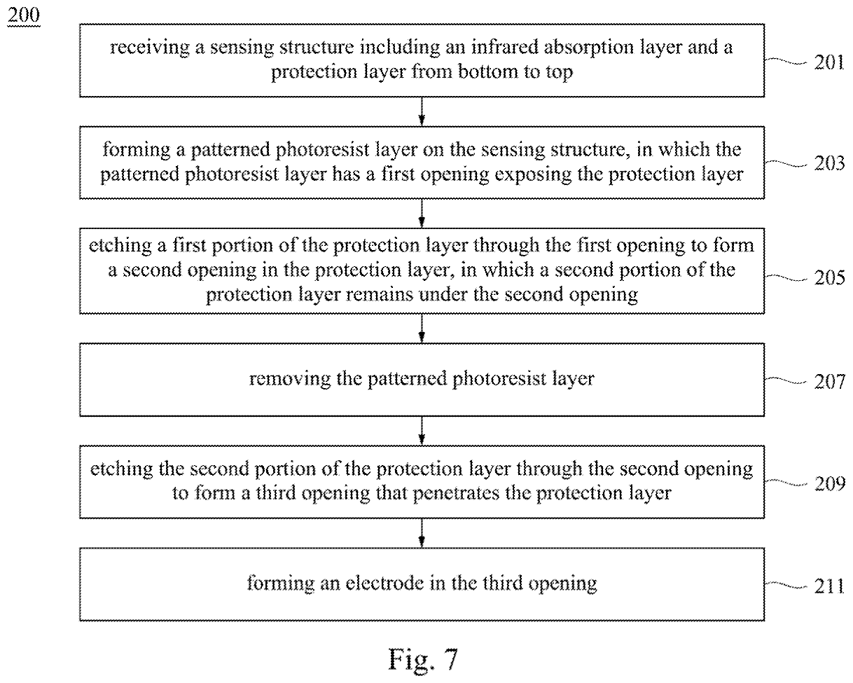

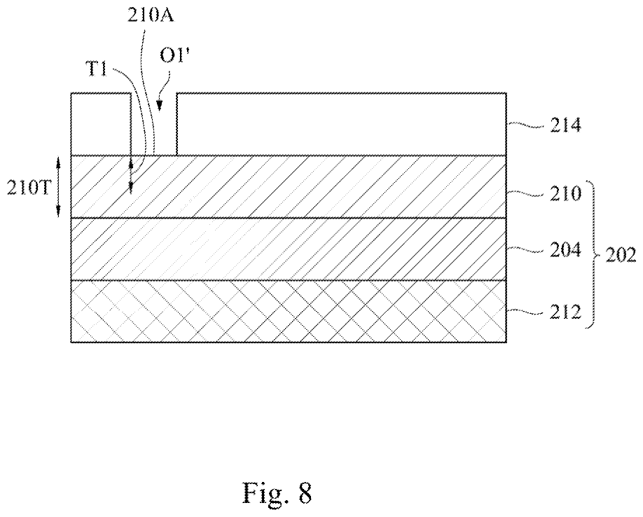

FIG. 7 is a flowchart of a method 200 of forming an infrared detector in accordance with some embodiments of the present disclosure. FIGS. 8 to 12 are schematics of the infrared detector during the formation stages in the method 200 shown in FIG. 7, in accordance with some embodiments of the present disclosure. Please refer to FIGS. 8 to 12 when reading FIG. 7.

In FIG. 7, the method 200 includes an operation 201. A sensing structure 202 is received, in which the sensing structure 202 includes an infrared absorption layer 204 and a protection layer 210, which are stacked from bottom to top, as shown in FIG. 8. The infrared absorption layer 204 can absorb infrared light and change the resistance value by changing its temperature. The protection layer 210 protect the infrared absorption layer 204 located underneath, in order to avoid ambient moisture and/or oxygen affecting the functional performances of the infrared absorption layer 204. In addition, the protection layer 210 may also absorb infrared light, thereby not affecting the function performances of the infrared absorption layer 204 while protecting the infrared absorption layer 204. In some embodiments, the infrared absorption layer 204 includes vanadium oxide, vanadium, titanium, amorphous silicon, or combinations thereof. In some embodiments, the protection layer 210 includes silicon nitride, silicon oxide, tetraethoxysilane, or combinations thereof. A thickness 210T of the protection layer 210 is between 600 Å and 1000 Å. In some embodiments, the sensing structure 202 further includes a buffer layer 212 located below the infrared absorption layer 204. The buffer layer 212 protects the infrared absorption layer 204 to avoid ambient moisture and/or oxygen affecting the functional performance of the infrared absorption layer 204. In some embodiments, the buffer layer 212 includes silicon nitride, silicon oxide, tetraethoxysilane, or combinations thereof.

In FIG. 7, the method 200 includes an operation 203. A patterned photoresist layer 214 is formed on the sensing structure 202, in which the patterned photoresist layer 214 has a first opening O1′ exposing the protection layer 210, as shown in FIG. 8. In some embodiments, a photoresist layer (not shown) is formed on the sensing structure 202, and then a portion of the photoresist layer is selectively exposed to actinic radiation. When the material of the photoresist layer includes a positive photoresist, the portion of the photoresist layer that is exposed to actinic radiation is removed during the development process, and the non-exposed portion of the photoresist layer that is not exposed to actinic radiation is remained during the development process. After the development process, the first opening O1′ of the patterned photoresist layer 214 is formed, as shown in FIG. 8. When the material of the photoresist layer includes a negative photoresist, the portion of the photoresist layer that is exposed to actinic radiation is remained during the development process, and the non-exposed portion of the photoresist layer that is not exposed to actinic radiation is removed during the development process. After the development process, the first opening O1′ of the patterned photoresist layer 214 is formed, as shown in FIG. 8. In some embodiments, the material of the patterned photoresist layer 214 includes poly(methyl methacrylate) (PMMA), epoxy resin, phenolic resin, etc.

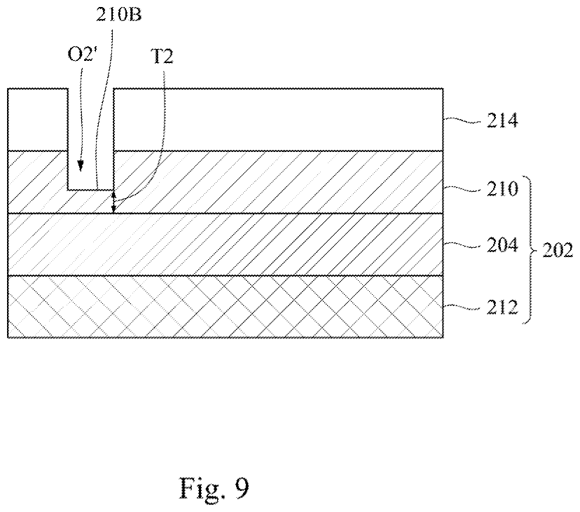

In FIG. 7, the method 200 includes an operation 205. A first portion 210A (see FIG. 6) of the protection layer 210 is etched through the first opening O1′ to form a second opening O2′ in the protection layer 210, in which a second portion 210B of the protection layer 210 remains under the second opening O2′, as shown in FIG. 9. In some embodiments, a first thickness T1 of the first portion 210A is between 500 Å and 700 Å, and a second thickness T2 of the second portion 210B is between 100 Å and 300 Å. In some embodiments, etching the first portion 210A of the protection layer 210 through the first opening O1′ is performed by using an etching gas that includes Cl₂, BCl₃, or a combination thereof.

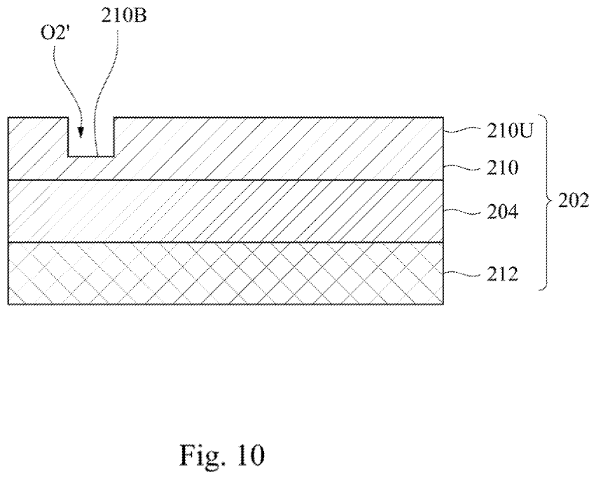

In FIG. 7, the method 200 includes an operation 207. The patterned photoresist layer 214 is removed, as shown in FIG. 10. In some embodiments, removing the patterned photoresist layer 214 is performed by using oxygen plasma.

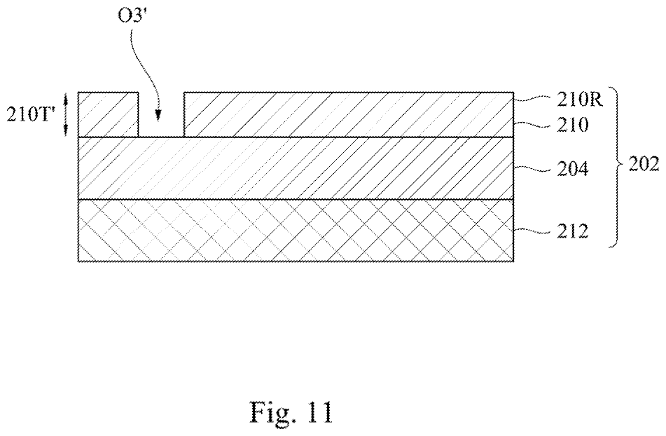

In FIG. 7, the method 200 includes an operation 209. The second portion 210B of the protection layer 210 is etched through the second opening O2′ to form a third opening O3′ that penetrates the protection layer 210, in which the third opening O3′ exposes the infrared absorption layer 204, as shown in FIG. 11. The operation 209 further includes etching an upper portion 210U of the protection layer 210 (see FIG. 10) when etching the second portion 210B of the protection layer 210 through the second opening O2′, thereby reducing the thickness of the protection layer 210 (see FIG. 11). After etching the upper portion 210U of the protection layer 210, the protection layer 210 has a remaining portion 210R on the infrared absorption layer 204, and when the third opening O3′ is formed, the third opening O3′ penetrates the remaining portion 210R of the protection layer 210. In the operation 209, the whole upper surface of the protection layer 210 is etched to avoid using the photoresist in the operation of forming the third opening O3′, thereby avoiding damaging the infrared absorption layer 204 that is exposed by the third opening O3′ in the process of removing the photoresist. The operation 209 of not using the photoresist also avoids additional residue formed on the infrared absorption layer 204 that is exposed in the process of removing the photoresist. The additional residue may affect the functional performances of the infrared absorption layer 204. For example, additional oxides may form in the process of using the oxygen plasma to remove the photoresist. In some embodiments, a thickness 210T′ of the remaining portion 210R of the protection layer 210 is between 500 Å and 700 Å. In some embodiments, etching the second portion 210B of the protection layer 210 and the upper portion 210U of the protection layer 210 is performed by using an etching gas including Cl₂, BCl₃, or a combination thereof.

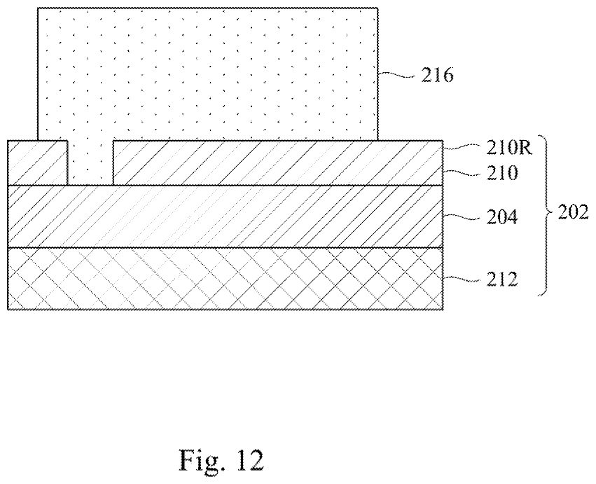

In FIG. 7, the method 200 includes an operation 211. An electrode 216 is formed in the third opening O3′, as shown in FIG. 12. The operation 211 further includes forming the electrode 216 on the protection layer 210 or on the remaining portion 210R of the protection layer 210. The electrode 216 is in direct contact with the infrared absorption layer 204 that is exposed by the third opening O3′. The electrode 216 with the connection to the external wires (not shown) measures the change in the resistance value of the infrared absorption layer 204. Because avoid using the photoresist in the formation of the third opening O3′, the electrode 216 formed in the operation 211 has a good contact surface with the infrared absorption layer 204. The good contact surface leads to small contact resistance, for example, the contact resistance being between 100 Kohm and 500 Kohm. The small contact resistance means the electrode 216 measures the changes in the resistance values caused by absorbing the infrared light in the infrared absorption layer 204 more accurately and sensitively. Also, because the measurement error is reduced, the change in the resistance value that the electrode 216 can measure is small. In some embodiments, the material of the electrode 216 includes titanium, titanium nitride, vanadium, tungsten, aluminum-copper (Al—Cu), aluminum-silicon-copper (Al—Si—Cu), or combinations thereof.

In contrast, in the comparative embodiment of using the photoresist to form the third opening (not drawn), the photoresist is formed on the sensing structure of FIG. 10. The photoresist has an opening on the second opening of FIG. 10. Later, the second portion of the protection layer that is under the second opening of FIG. 10 is etched through the opening of the photoresist. The result is the third opening of FIG. 11, which penetrates the protection layer. Later, the photoresist is removed and the electrode of FIG. 12 is formed in the third opening of FIG. 11. In the comparative embodiment, the third opening is formed by using the photoresist so that the process of removing the photoresist (e.g., a plasma process) damages the infrared absorption layer that is exposed by the third opening or leads to the residues formed on the exposed infrared absorption layer. The damage and the residues cause high contact resistance between the electrode and the infrared absorption layer in the comparative embodiment, for example, between 1000 Kohm and 1500 Kohm. The comparative embodiment failed to accurately and sensitively measure the change in the resistance value of the infrared absorption layer when absorbing the infrared light. The comparative embodiment also failed to measure a smaller change of the resistance value.

The present disclosure yet also relates to a method of forming infrared detector. The method includes the following operations. A sensing structure including an infrared absorption layer, a first protection layer, and a second protection layer from bottom to top is received, in which a material of the first protection layer is different than a material of the second protection layer. A patterned photoresist layer on the sensing structure is formed, in which the patterned photoresist layer has a first opening exposing the second protection layer. The second protection layer is etched through the first opening to form a second opening in the second protection layer, in which the second opening exposes the first protection layer. The patterned photoresist layer is removed. The first protection layer is etched through the second opening to form a third opening that penetrates the second protection layer and the first protection layer, in which the third opening exposes the infrared absorption layer. An electrode is formed in the third opening. The method of forming infrared detector in the present disclosure will be explained in detail in the following paragraphs.

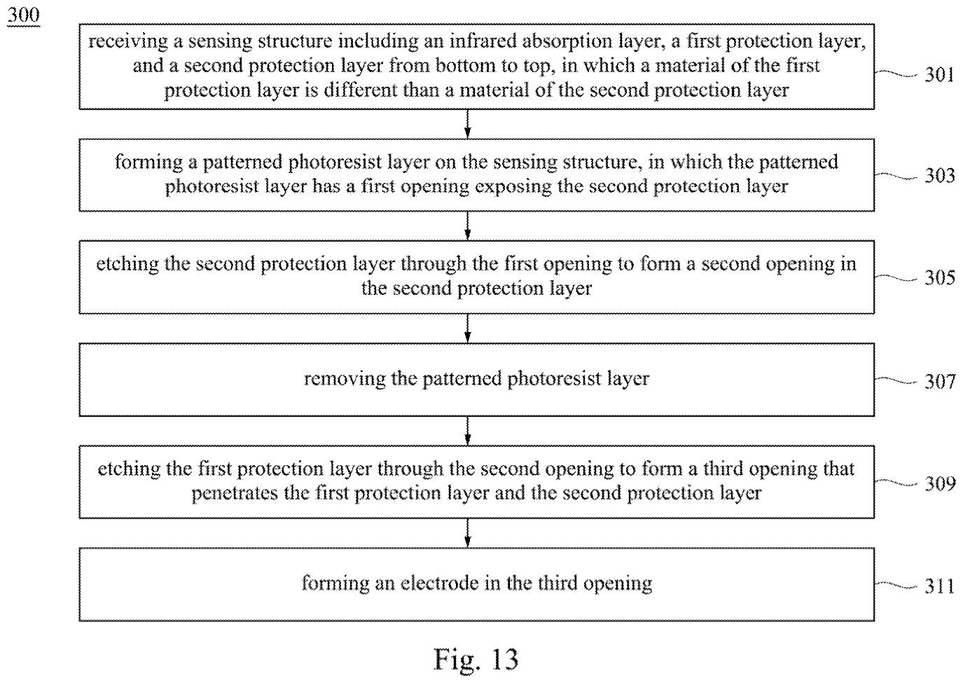

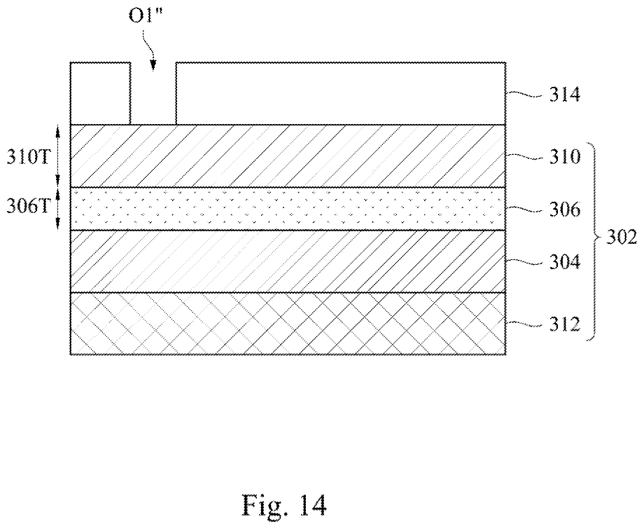

FIG. 13 is a flowchart of a method 300 of forming an infrared detector in accordance with some embodiments of the present disclosure. FIGS. 14 to 18 are schematics of the infrared detector during the formation stages in the method 300 shown in FIG. 13, in accordance with some embodiments of the present disclosure. Please refer to FIGS. 14 to 18 when reading FIG. 13.

In FIG. 13, the method 300 includes an operation 301. A sensing structure 302 is received. The sensing structure 302 includes an infrared absorption layer 304, a first protection layer 306, and a second protection layer 310, which are stacked from bottom to top as shown in FIG. 14, in which the material of the first protection layer 306 is different than the material of the second protection layer 310. The infrared absorption layer 304 can absorb infrared light and change the resistance value by changing its temperature. The first protection layer 306 and the second protection layer 310 protect the infrared absorption layer 304 located underneath, in order to avoid ambient moisture and/or oxygen affecting the functional performance of the infrared absorption layer 304. In addition, the first protection layer 306 and the second protection layer 310 may also absorb infrared light, thereby not affecting the function performances of the infrared absorption layer 304 while protecting the infrared absorption layer 304. In some embodiments, the infrared absorption layer 304 includes vanadium oxide, vanadium, titanium, amorphous silicon, or combinations thereof. In some embodiments, the first protection layer 306 includes silicon nitride, silicon oxide, tetraethoxysilane, or combinations thereof. The second protection layer 310 includes silicon nitride, silicon oxide, tetraethoxysilane, or combinations thereof but is different than the first protection layer 306. In some embodiments, a thickness 306T of the first protection layer 306 is between 300 Å and 500 Å, and a thickness 310T of the second protection layer 310 is between 1000 Å and 1500 Å. In some embodiments, the sensing structure 302 further includes a buffer layer 312 located below the infrared absorption layer 304. The buffer layer 312 protects the infrared absorption layer 304 to avoid ambient moisture and/or oxygen affecting the functional performance of the infrared absorption layer 304. In some embodiments, the buffer layer 312 includes silicon nitride, silicon oxide, tetraethoxysilane, or combinations thereof.

In FIG. 13, the method 300 includes an operation 303. A patterned photoresist layer 314 is formed on the sensing structure 302, in which the patterned photoresist layer 314 has a first opening O1″ exposing the second protection layer 310, as shown in FIG. 14. In some embodiments, a photoresist layer (not shown) is formed on the sensing structure 302, and then a portion of the photoresist layer is selectively exposed to actinic radiation. When the material of the photoresist layer includes a positive photoresist, the portion of the photoresist layer that is exposed to actinic radiation is removed during the development process, and the non-exposed portion of the photoresist layer that is not exposed to actinic radiation is remained during the development process. After the development process, the first opening O1″ of the patterned photoresist layer 314 is formed, as shown in FIG. 14. When the material of the photoresist layer includes a negative photoresist, the portion of the photoresist layer that is exposed to actinic radiation is remained during the development process, and the non-exposed portion of the photoresist layer that is not exposed to actinic radiation is removed during the development process. After the development process, the first opening O1″ of the patterned photoresist layer 314 is formed, as shown in FIG. 14. In some embodiments, the material of the patterned photoresist layer 314 includes poly(methyl methacrylate) (PMMA), epoxy resin, phenolic resin, etc.

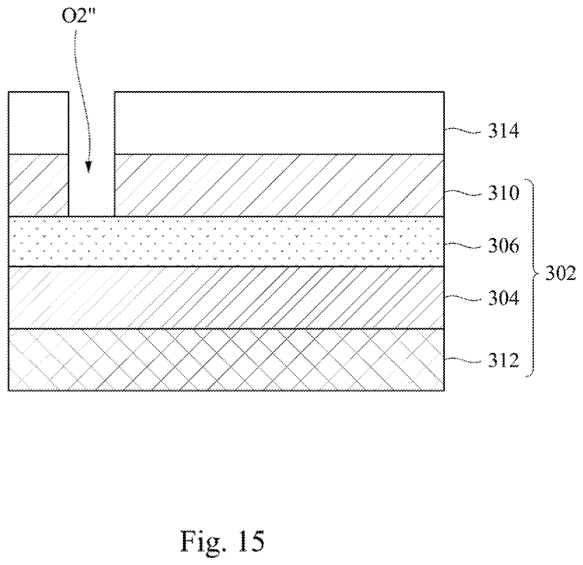

In FIG. 13, the method 300 includes an operation 305. The second protection layer 310 is etched through the first opening O1″ to form a second opening O2″ in the second protection layer 310, in which the second opening O2″ exposes the first protection layer 306, as shown in FIG. 15. In some embodiments, etching the second protection layer 310 through the first opening O1″ is performed by using an etching gas that includes Cl₂, BCl₃, or a combination thereof.

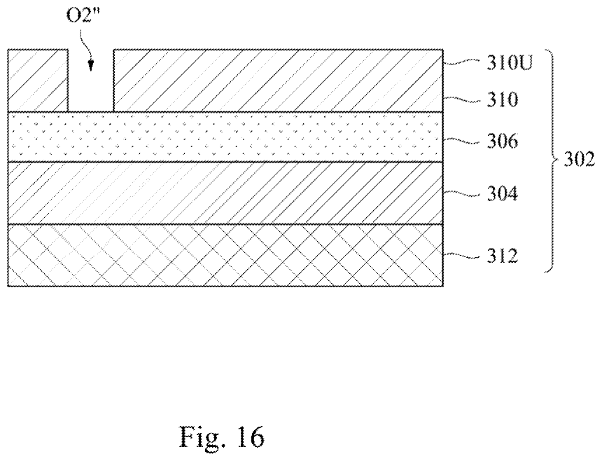

In FIG. 13, the method 300 includes an operation 307. The patterned photoresist layer 314 is removed, as shown in FIG. 16. In some embodiments, removing the patterned photoresist layer 314 is performed by using oxygen plasma.

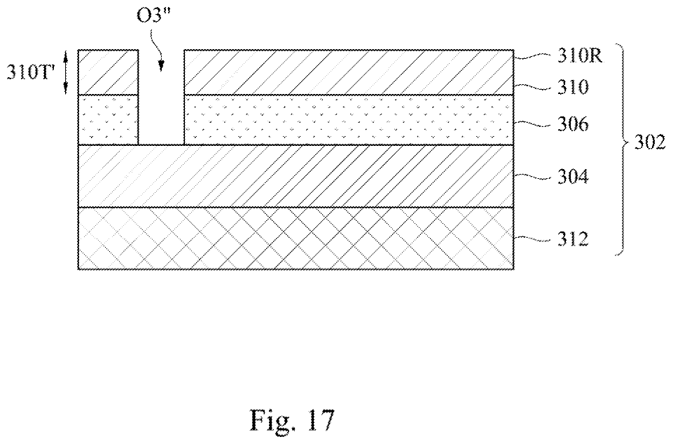

In FIG. 13, the method 300 includes an operation 309. The first protection layer 306 is etched through the second opening O2″ to form a third opening O3″ that penetrates the second protection layer 310 and the first protection layer 306, in which the third opening O3″ exposes the infrared absorption layer 304, as shown in FIG. 17. The operation 309 further includes etching an upper portion 310U of the second protection layer 310 (see FIG. 16) when etching the first protection layer 306 through the second opening O2″, thereby reducing the thickness of the second protection layer 310 (see FIG. 17). After etching the upper portion 310U of the second protection layer 310, the second protection layer 310 has a remaining portion 310R on the first protection layer 306, and when the third opening O3″ is formed, the third opening O3″ penetrates the remaining portion 310R of the second protection layer 310 and the first protection layer 306. In the operation 309, the whole upper surface of the second protection layer 310 is etched. In the operation 309, the first protection layer 306 that is exposed by the second opening O2″ of the second protection layer 310 is etched through the second opening O2″ of the second protection layer 310. The operation of forming the third opening O3″ avoids using the photoresist, thereby avoiding damaging the infrared absorption layer 304 that is exposed by the third opening O3″ in the process of removing the photoresist. The operation 309 of not using the photoresist also avoids additional residue formed on the infrared absorption layer 304 that is exposed in the process of removing the photoresist. The additional residue may affect the functional performances of the infrared absorption layer 304. For example, additional oxides may form in the process of using the oxygen plasma to remove the photoresist. In some embodiments, a thickness 310T′ of the remaining portion 310R of the second protection layer 310 is between 500 Å and 1200 Å. In some embodiments, etching the first protection layer 306 and the upper portion 310U of the second protection layer 310 is performed by using an etching gas including Cl₂, BCl₃, or a combination thereof.

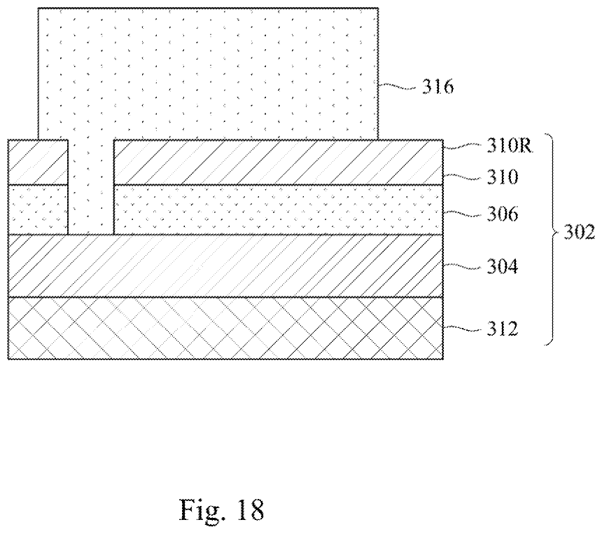

In FIG. 13, the method 300 includes an operation 311. An electrode 316 is formed in the third opening O3″, as shown in FIG. 18. The operation 311 further includes forming the electrode 316 on the second protection layer 310 or on the remaining portion 310R of the second protection layer 310. The electrode 316 is in direct contact with the infrared absorption layer 304 that is exposed by the third opening O3″. The electrode 316 with the connection to the external wires (not shown) measures the change in the resistance value of the infrared absorption layer 304. Because avoid using the photoresist in the formation of the third opening O3″, the electrode 316 formed in the operation 311 has a good contact surface with the infrared absorption layer 304. The good contact surface leads to small contact resistance. The small contact resistance means the electrode 316 measures the change in the resistance value caused by absorbing the infrared light in the infrared absorption layer 304 more accurately and sensitively. Also, because the measurement error is reduced, the change in the resistance value that the electrode 316 can measure is small. In some embodiments, the material of the electrode 316 includes titanium, titanium nitride, vanadium, tungsten, aluminum-copper (Al—Cu), aluminum-silicon-copper (Al—Si—Cu), or combinations thereof.

In contrast, in the comparative embodiment of using the photoresist to form the third opening (not drawn), the photoresist is formed on the sensing structure of FIG. 16. The photoresist has an opening on the second opening of FIG. 16. Later, the first protection layer that is under the second opening of FIG. 16 is etched through the opening of the photoresist. The result is the third opening of FIG. 17, which penetrates the second protection layer and the first protection layer. Later, the photoresist is removed and the electrode of FIG. 18 is formed in the third opening of FIG. 17. In the comparative embodiment, the third opening is formed by using the photoresist so that the process of removing the photoresist (e.g., a plasma process) damages the infrared absorption layer that is exposed by the third opening or leads to the residues formed on the exposed infrared absorption layer. The damage and the residues cause high contact resistance between the electrode and the infrared absorption layer in the comparative embodiment. The comparative embodiment failed to accurately and sensitively measure the change in the resistance value of the infrared absorption layer when absorbing the infrared light. The comparative embodiment also failed to measure a smaller change of the resistance value.

The methods of forming infrared detector in the present disclosure make the electrode and the sensing material (e.g., the first infrared absorption layer, the second infrared absorption layer, and the infrared absorption layer mentioned above) have a good connection surface. The contact resistance of the connection surface is small. The small contact resistance makes the electrode to measure the changes in the resistance values of the sensing materials more accurately and sensitively after absorbing the infrared light. In addition, because the measurement error is small, the change in the resistance value that the electrode can measure is also small, thereby having a better detection limit.

The present disclosure is described in considerable detail with some embodiments. Other embodiments may be feasible. The scope and spirit of the claims that are appended should not be limited only to the description of the embodiments in the present disclosure.

For one skilled in the art, the present disclosure may be modified and changed as long as not departing from the spirit and scope of the present disclosure. If the modifications and changes are within the scope and spirit of the claims that are appended, they are covered by the present disclosure.

What is claimed is:

1. A method of forming infrared detector, comprising:
receiving a sensing structure comprising a first infrared absorption layer, a first protection layer, a second infrared absorption layer, and a second protection layer from bottom to top;
forming a patterned photoresist layer on the sensing structure, wherein the patterned photoresist layer has a first opening exposing the second protection layer;
etching the second protection layer through the first opening to form a second opening in the second protection layer, wherein the second opening exposes the second infrared absorption layer;
removing the patterned photoresist layer;
etching the second infrared absorption layer and the first protection layer through the second opening to form a third opening that penetrates the second protection layer, the second infrared absorption layer, and the first protection layer, wherein the third opening exposes the first infrared absorption layer; and
forming an electrode in the third opening.

2. The method of claim 1, wherein the electrode is in direct contact with the first infrared absorption layer.

3. The method of claim 1, wherein the first protection layer and the second protection layer independently comprise silicon nitride, silicon oxide, tetraethoxysilane, or combinations thereof.

4. The method of claim 1, wherein a thickness of the second protection layer is greater than a thickness of the first protection layer.

5. The method of claim 1, wherein a thickness of the second protection layer is between 1500 Å and 2500 Å.

6. The method of claim 1, wherein the second infrared absorption layer comprises titanium, vanadium, amorphous silicon, or combinations thereof.

7. The method of claim 1, wherein a thickness of the second infrared absorption layer is between 100 Å and 200 Å.

8. The method of claim 1, wherein the first infrared absorption layer comprises vanadium oxide, vanadium, titanium, amorphous silicon, or combinations thereof.

9. The method of claim 1, wherein etching the second infrared absorption layer and the first protection layer through the second opening is performed by using an etching gas that comprises Cl₂, BCl₃, or a combination thereof.

10. The method of claim 1, further comprising etching an upper portion of the second protection layer when etching the second infrared absorption layer and the first protection layer through the second opening.

11. The method of claim 10, wherein the second protection layer has a remaining portion on the second infrared absorption layer after etching the upper portion of the second protection layer.

12. The method of claim 11, wherein a thickness of the remaining portion of the second protection layer is between 800 Å and 1900 Å.

13. A method of forming infrared detector, comprising:
receiving a sensing structure comprising an infrared absorption layer and a protection layer from bottom to top;
forming a patterned photoresist layer on the sensing structure, wherein the patterned photoresist layer has a first opening exposing the protection layer;
etching a first portion of the protection layer through the first opening to form a second opening in the protection layer, wherein a second portion of the protection layer remains under the second opening;
removing the patterned photoresist layer;
etching the second portion of the protection layer through the second opening to form a third opening that penetrates the protection layer, wherein the third opening exposes the infrared absorption layer; and
forming an electrode in the third opening.

14. The method of claim 13, wherein the protection layer comprises silicon nitride, silicon oxide, tetraethoxysilane, or combinations thereof.

15. The method of claim 13, wherein the infrared absorption layer comprises vanadium oxide, vanadium, titanium, amorphous silicon, or combinations thereof.

16. The method of claim 13, further comprising etching an upper portion of the protection layer when etching the second portion of the protection layer through the second opening.

17. A method of forming infrared detector, comprising:
receiving a sensing structure comprising an infrared absorption layer, a first protection layer, and a second protection layer from bottom to top, wherein a material of the first protection layer is different than a material of the second protection layer;
forming a patterned photoresist layer on the sensing structure, wherein the patterned photoresist layer has a first opening exposing the second protection layer;
etching the second protection layer through the first opening to form a second opening in the second protection layer, wherein the second opening exposes the first protection layer;
removing the patterned photoresist layer;
etching the first protection layer through the second opening to form a third opening that penetrates the first protection layer and the second protection layer, wherein the third opening exposes the infrared absorption layer; and
forming an electrode in the third opening.

18. The method of claim 17, wherein the first protection layer comprises silicon nitride, silicon oxide, tetraethoxysilane, or combinations thereof, and the second protection layer comprises silicon nitride, silicon oxide, tetraethoxysilane, or combinations thereof.

19. The method of claim 17, wherein the infrared absorption layer comprises vanadium oxide, vanadium, titanium, amorphous silicon, or combinations thereof.

20. The method of claim 17, further comprising etching an upper portion of the second protection layer when etching the first protection layer through the second opening.
